(19) United States
(12) Patent Application Publication
(10) Pub. No.: US 2015/0044812 A1
(43) Pub. Date: Feb. 12, 2015

(54) NON-ACIDIC ISOTROPIC ETCH-BACK FOR SILICON WAFER SOLAR CELLS

(71) Applicants: Prabir Kanti Basu, Singapore (SG); Matthew Benjamin Boreland, Singapore (SG); Debajyoti Sarangi, Singapore (SG); Vinodh Shanmugam, Singapore (SG)

(72) Inventors: Prabir Kanti Basu, Singapore (SG); Matthew Benjamin Boreland, Singapore (SG); Debajyoti Sarangi, Singapore (SG); Vinodh Shanmugam, Singapore (SG)

(73) Assignee: NATIONAL UNIVERSITY OF SINGAPORE, Singapore (SG)

(21) Appl. No.: 14/385,577

(22) PCT Filed: May 9, 2013
(86) PCT No.: PCT/SG2013/000183

§ 371 Date: Sep. 16, 2014

Related U.S. Application Data
(60) Provisional application No. 61/644,730, filed on May 9, 2012.

(51) Int. Cl. H01L 31/18; H01L 31/0216

(52) U.S. Cl. CPC H01L 31/1804; H01L 31/02168
USPC 438/72; 438/57

(57) ABSTRACT

A method for solar cell fabrication is provided. The method includes etching a doped surface of a silicon wafer solar cell using a solution including potassium hydroxide (KOH) and sodium hypochlorite (NaOCl). Alternatively the solution could include sodium hydroxide (NaOH) and NaOCl. In one aspect, the step of back-etching an emitter of the solar cell using the KOH:NaOCl solution is simultaneously performed with porous silicon removal. In another aspect, the step of back-etching the emitter of the solar cell using the KOH:NaOCl solution also includes PSG removal. And in yet another aspect, the step of back-etching the emitter of the solar cell using the KOH:NaOCl solution is performed simultaneously with polishing.

### PRIORITY CLAIM

The present application claims priority to U.S. Patent Application No. 61/644,730, filed 9 May, 2012.

### FIELD OF THE INVENTION

The present invention generally relates to solar cell manufacturing, and more particularly relates to methods and systems for etch-back for silicon wafer solar cells.

### BACKGROUND OF THE DISCLOSURE

Silicon wafer solar cells are one of the dominant technologies for industrial manufacturing of photovoltaic solar cells. Current silicon wafer solar cell manufacturing techniques utilize silicon wafers and various fabrication techniques including etching of the silicon wafer solar cells. For example, chemical etching can be used during several process steps in the fabrication process of silicon wafer solar cells, such as an emitter etch-back process step, a post PSG contamination removal process step and a parasitic junction removal process step.

Emitter etch-back is a process that partially removes the emitter layer on the silicon wafer. This is typically done to optimize dopant surface concentration such as removing heavily doped surface layers, known as “surface dead layers”, that occur in inline or tube diffused emitters, or dopant depleted or rich regions that occur in boron diffusion. Etch-back also allows the formation of high sheet resistance emitters from a low sheet resistance precursor emitter in, for example, the formation of either homogenous or selective emitters. In the case of selective emitters, the etch-back is typically masked to produce selective etching to result in patterning of the sheet resistance of the emitter.

Emitter etch-back solutions are typically acidic and based on hydrofluoric acid—(HF), such as hydrofluoric:nitric acid (HF—HNO₃) solutions. However, these solutions represent a significant safety hazard and require complex waste disposal. In addition, these solutions also remove dielectrics such as SiNₓ and SiOₓ, making them incompatible for masked etching using dielectric masks.

Solar cell fabrication using inline diffused emitters (ILDE) is a low cost industry method for emitter formation. After the formation of an emitter by this process and subsequent removal of the PSG in HF, the emitter surface is covered with difficult to remove contaminants. These surface contaminants reduce the electrical performance of the solar cell. Conventional methods use extended and/or higher concentration HF-based etching to remove these surface contaminants, which is not always fully effective and suffers from the safety hazards and dielectric removal drawbacks described above.

During emitter or p-n junction formation on standard solar cells, dopants are impregnated into a sunny-side surface of the silicon wafer by, for example, thermal diffusion. However, typically dopants are unintentionally impregnated into the opposite side and edges of the wafer thereby forming a parasitic junction. The parasitic junction causes a shunt which degrades the efficiency of the solar cell.

One way to remove the shunt is to chemically etch off the parasitic junction. The standard approach is single-side etching using a cooled solution of HF:HNO₃ based etchant to remove the parasitic junction. Sulphuric acid (H₂SO₄) or acetic acid may also be added to the solution. Because the HF-based solutions also etch dielectrics (e.g. SiNₓ, SiOₓ), the parasitic junction removal must necessarily be done before the SiNₓ passivation step of the process

Thus, what is needed is a solar cell fabrication process that overcomes these drawbacks of conventional etching process steps, such as providing an etch-back solution that is compatible with dielectrics and does not have the safety hazards present in HF-based etching process steps. Furthermore, other desirable features and characteristics will become apparent from the subsequent detailed description and the appended claims, taken in conjunction with the accompanying drawings and this background of the disclosure.

### SUMMARY

According to the Detailed Description, a method for solar cell fabrication is presented. The method includes etching a doped surface of a silicon wafer solar cell using a solution including potassium hydroxide (KOH) and sodium hypochlorite (NaOCl). Alternatively the solution could include sodium hydroxide (NaOH) and NaOCl.

In accordance with another aspect, another method for silicon wafer solar cell fabrication is provided. The method includes using a solution including potassium hydroxide (KOH) and sodium hypochlorite (NaOCl) to simultaneously etch-back an emitter layer of the silicon wafer solar cell while removing porous silicon.

In accordance with a further aspect, yet another method for silicon wafer solar cell fabrication is provided. The method includes using a solution including potassium hydroxide (KOH) and sodium hypochlorite (NaOCl) to simultaneously etch-back an emitter layer of the silicon wafer solar cell while polishing a surface of the emitter layer of the silicon wafer.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with a present invention.

FIG. 1, comprising FIGS. 1A and 1B, illustrates conventional diffusion techniques for silicon wafer solar cell fabrication, wherein FIG. 1A illustrates tube diffusion and FIG. 1B illustrates in-line diffusion.

FIG. 2 illustrates a conventional post-diffusion process flow for silicon wafer solar cell fabrication.

FIG. 3 illustrates a more detailed conventional post-diffusion process flow for silicon wafer solar cell fabrication including emitter etch-back.

FIG. 4, comprising FIGS. 4A, 4B, 4C and 4D, depicts illustrations of a post-diffusion emitter etch-back process on a silicon wafer solar cell, wherein FIG. 4A is a diagram which depicts the wafer before etch-back and FIG. 4B is a diagram that depicts the wafer after etch-back, and wherein FIG. 4C is a scanning electron microscope (SEM) micrograph depicting the wafer after PSG removal and before etch-back in accordance with the present embodiment and FIG. 4D is a SEM micrograph depicting the wafer after etch-back in accordance with the present embodiment.

FIG. 5 illustrates side-by-side comparison of the conventional process flow of FIG. 3 as compared to a process flow in accordance with a present embodiment.

FIG. 6, comprising FIGS. 6A and 6B, illustrates SEM micrographs of a post-diffusion emitter etch-back process on a multi-crystalline silicon wafer solar cell in accordance with the present invention, wherein FIG. 6A illustrates a SEM micrograph of an in-line phosphorus diffused layer before etch-back of a multi-crystalline silicon wafer and FIG. 6B illustrates a SEM micrograph of the in-line phosphorus diffused layer after etch-back of the multi-crystalline silicon wafer in accordance with the present embodiment.

FIG. 7, comprising FIGS. 7A and 7B, illustrates SEM micrographs of a post-diffusion emitter etch-back process on a silicon wafer solar cell in accordance with the present invention, wherein FIG. 7A illustrates a SEM micrograph of a tube boron diffused layer before etch-back of a crystalline silicon wafer and FIG. 7B illustrates a SEM micrograph of the tube boron diffused layer after etch-back of the crystalline silicon wafer in accordance with the present embodiment.

FIG. 8 illustrates a bar graph depicting variations of weighted averages of reflectance (WAR) of a boron diffused layer before and after etch-back of different durations in accordance with the present embodiment.

FIG. 9 illustrates a bar graph depicting variations of weighted averages of reflectance (WAR) of a phosphorous diffused layer before and after etch-back of different durations in accordance with the present embodiment.

FIG. 10 illustrates side-by-side comparison of the conventional process flows of FIG. 5 as compared to process flows in accordance with a first variant of the present embodiment which combines emitter etch-back process steps with the porous silicon removal step of the standard parasitic-junction/PSG removal process.

FIG. 11 illustrates a graph of differential sheet resistance before and after etch-back in accordance with the present embodiment for tube and inline-diffused mono- and multi-crystalline wafers with a PSG layer on the emitter.

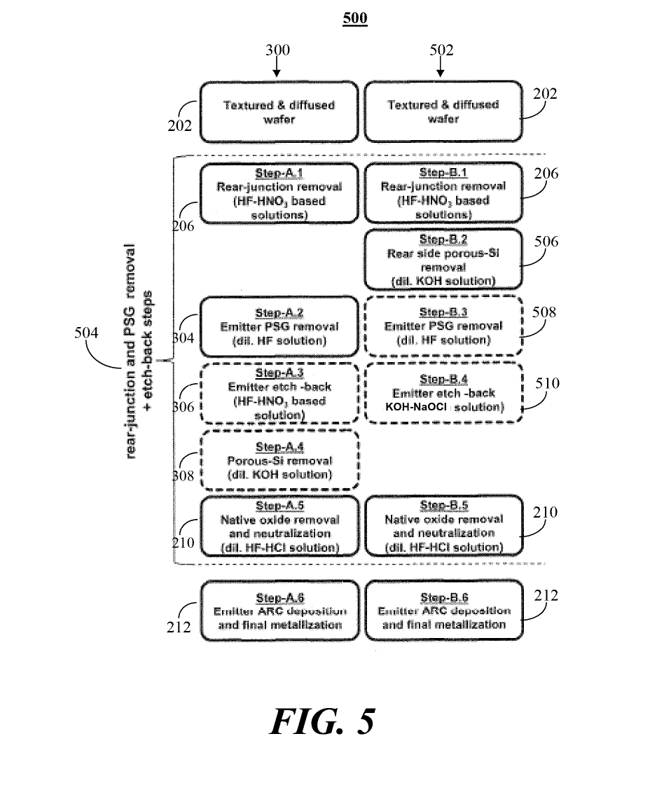

And FIG. 12 illustrates side-by-side comparison of a process flow of FIG. 5 as compared to process flows in accordance with a second variant of the present embodiment which combines emitter etch-back process steps with rear surface polishing.

Skilled artisans will appreciate that elements in the figures are illustrated for simplicity and clarity and have not necessarily been depicted to scale. For example, the dimensions of some of the elements in the block diagrams may be exaggerated in respect to other elements to help to improve understanding of the present embodiments.

### DETAILED DESCRIPTION

The following detailed description is merely exemplary in nature and is not intended to limit the invention or the application and uses of the invention. Furthermore, there is no intention to be bound by any theory presented in the preceding background of the invention or the following detailed description. It is the intent to present methods for improved etching processes based on a combination of potassium hydroxide (KOH) and sodium hypochlorite (NaOCl) solutions or based on a combination of sodium hydroxide (NaOH) and NaOCl solutions and the use of such etching processes in mono- and multi-crystalline silicon wafer solar cell fabrication.

The etching process utilizing the combination of KOH (or NaOH) and NaOCl in accordance with embodiments presented herein advantageously provides controlled, slow, uniform and near-conformal etching of doped silicon surfaces that preserves the surface texture of silicon wafers, making this process highly suitable for etch-back technologies. In addition, the etch-back solution in accordance with the present embodiment is largely non-reactive with silicon nitrides (SiNₓ) and silicon oxides (SiOₓ) (as opposed to conventional acid-based etch back solutions (e.g., based on HF), thus allowing SiNₓ or SiOₓ to be used as an etching mask to enable single-side or patterned etch-backs. Further, in accordance with the embodiments presented herein, the KOH/NaOH—NaOCl etch-back solution successfully removes surface contaminants left after phosphosilicate glass (PSG) removal on inline diffused emitters.

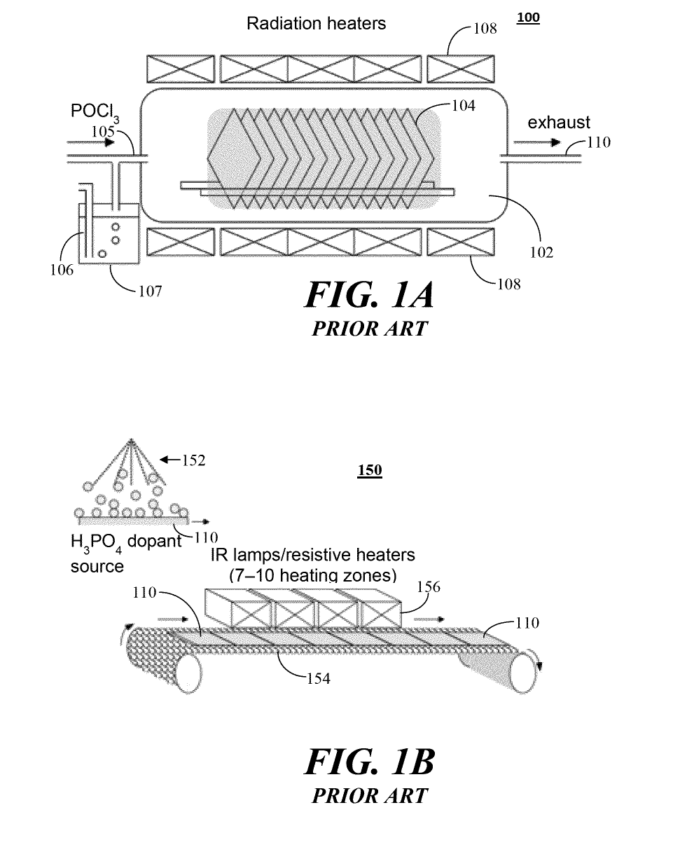

Referring to FIGS. 1A and 1B, conventional fabrication techniques for emitters on silicon wafer solar cells typically comprise either boron or phosphorous diffusion. Batch-based tube diffusion depicted in an illustration 100 (FIG. 1A) using a high-purity phosphorus oxychloride (POCl₃) liquid dopant source is the de-facto standard for emitter formation in the photovoltaic industry. Inline-diffusion depicted in an illustration 150 (FIG. 1B) is an alternate process for emitter formation, which uses spray-on solutions of orthophosphoric acid (H₃PO₄) as the dopant source. The illustrations 100, 150 are industry standard process illustrations from PV-Tech.org, Inline diffusion benefits from shorter diffusion times, reduced automation requirements, simpler wafer loading and low cost dopant solutions. However, the short diffusion times used for inline diffused emitters typically results in a surface dead layer (due to surface contaminants and a high dopant concentration at the surface), which tends to limit open circuit voltage (V_{oc}) and efficiency of inline diffused solar cells compared to tube-diffused. Effective reduction or removal of this heavily doped dead layer and surface contaminants is essential for achieving higher efficiencies using inline-diffusion. Various cleaning or etching processes have been developed to remove this dead layer and surface contaminants including the so called “emitter etch-back” process. One skilled in the art will recognize that tube diffused emitters also have surface dead-layers, albeit at a lower level, and therefore will also benefit from “emitter etch-back” processes.

Referring to FIG. 1A, the illustration 100 depicts conventional tube diffusion wherein an quartz tube 102 inside a furnace of radiation heaters (108) is used for batch based (i.e., vertical or horizontal wafers 104) emitter formation on the silicon wafers 104 by providing phosphorus oxychloride (POCl₃) vapour at an intake 105 by passing a nitrogen carrier gas 106 through a bubbler 107 of POCl₃ liquid. An exhaust 110 removes excess gas from the oven 102.

Referring to FIG. 1B, the illustration 150 depicts conventional horizontal in-line chemical diffusion where phosphoric acid (H₃PO₄) 152 is sprayed over one or both surfaces of the silicon wafer 110 and then the silicon wafer 110 is driven on a belt 154 under infrared lamps and/or resistive heaters 156 in several heating zones (typically seven to ten heating zones) to form emitters on the silicon wafers 110.

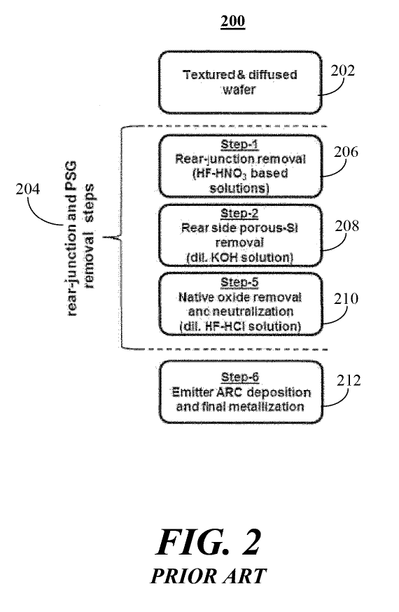

Referring to FIG. 2, a conventional post-diffusion process flow 200 starts with texturing and diffusing the silicon wafer at step 202 for either acidic-isotropic textured multi-crystalline silicon or alkaline-anisotropic textured mono-crystalline silicon. Then, parasitic junction removal and PSG removal is performed at the collection of steps marked 204. First, the parasitic junction is removed at step 206, then the rear-side porous silicon is removed at step 208. Finally, the native oxide is removed and neutralized at step 210. After the native oxide removal at step 210, the emitter anti-reflective coating (ARC) is deposited and final metallization is performed at step 212. Both of steps 206 and 210 in conventional silicon wafer solar cell fabrication disadvantageously require the use of hydrofluoric acid based solutions (e.g., HF—HNO₃ and HF—HCl).

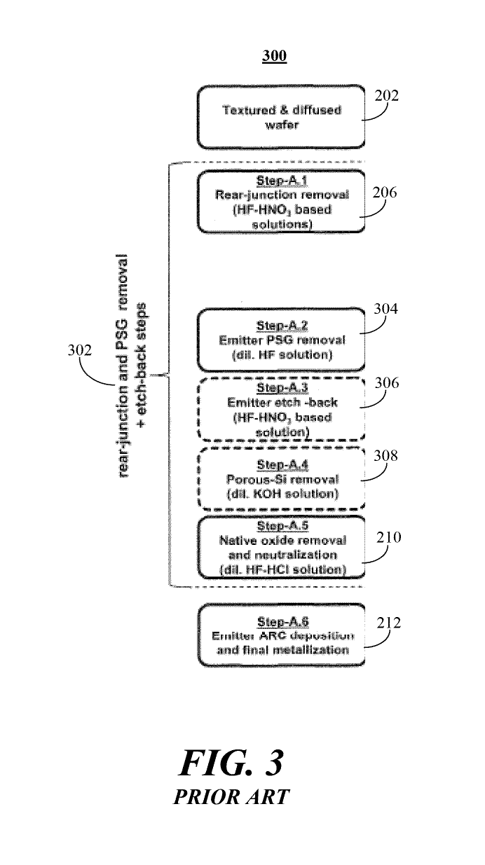

Referring to FIG. 3, a further conventional post-diffusion process flow 300 includes parasitic junction and PSG removal as well as etch-back at the collection of steps marked 302. After the parasitic junction is removed at the step 206, the emitter PSG is removed with a hydrogen fluoride (HF) solution at step 304. The emitter is etched back with a HF—HNO₃ solution at step 306 and the porous silicon is removed with a potassium hydroxide (KOH) solution at step 308.

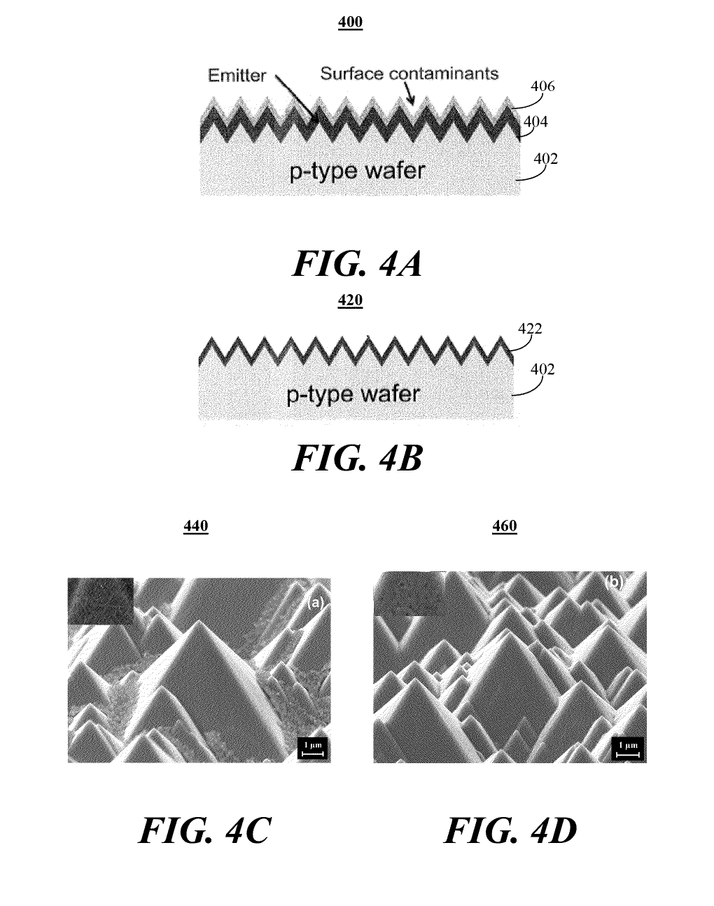

Emitter etch-back is illustrated in FIG. 4, including FIGS. 4A, 4B, 4C and 4D. FIG. 4A depicts an illustration 400 of the silicon wafer solar cell 402 after formation of the emitter by diffusion 404. As can be seen from the illustration 400, the emitter 404 surface (after PSG removal) is covered with difficult to remove surface contaminants 406 left from the diffusion process. These surface contaminants 406 reduce the electrical performance of the solar cell. Referring to FIG. 4B, steps 304 and 306 remove the surface contaminants and etch-back the emitter 404 to a new surface 422. However, removal of these surface contaminants 406 at step 304 and emitter 404 etch-back at step 306 with the conventional HF-based etching approach is not always effective and suffer from associated safety hazards and dielectric removal drawbacks. In accordance with a present embodiment, a chemical etching process with a solution of hot KOH:NaOCl solution as a non-acidic, HF-free etch-back solution is proposed to overcome the safety and acidic-related issues present in conventional post-diffusion silicon wafer soar cell processing. As described above, another hydroxides, such as sodium hydroxide (NaOH), can be substituted for the potassium hydroxide (KOH) in the etch solution. As can be seen from FIGS. 4C and 4D, removal of the surface contaminants and etch-back with the hot KOH:NaOCl solution is quite effective and does not suffer from the drawbacks of the HF-based etching approach. FIG. 4C depicts a scanning electron microscope (SEM) micrograph 440 of the in-line-diffused mono-Si surface after PSG removal. A considerable amount of surface contaminants is visible in the micrograph 440 on the surface where the white scaling in the micrograph 440 represents the visible imprints of the surface contamination which will reduce the solar cell efficiency. The hot KOH:NaOCl etch solution, however, effectively removes the foreign material, while maintaining the conformity of the pyramids as shown in micrograph 460 of FIG. 4D. Basically the hot KOH:NaOCl etch solution removes the deposited hard surface contaminants arising from the in-line diffusion process and, as clearly shown in the micrograph 460, after etch-back there is an absence of surface contaminants, and just nanometer-size pinholes remaining in the clean silicon areas.

Referring to FIG. 5, a side-by-side flow diagram 500 depicts the conventional method 300 and an improved method 502 in accordance with the present embodiment. The difference between these two methods 300, 502 lies in the parasitic junction and PSG removal and etch-back steps 504. A rear-side porous silicon removal step 506 is performed after the parasitic junction removal step 206. Then, an emitter PSG removal step 508 is performed followed by an emitter etch-back step 510 involving etching an emitter surface 404 of the silicon wafer solar cell 402 using a solution including KOH and NaOCl in accordance with the present embodiment. The KOH:NaOCl solution provides controlled, uniform and near-conformal removal of doped/un-doped silicon layers on the crystalline silicon wafer solar cells. The controlled and uniform etching behaviour enables removal of unwanted heavily or depleted doped layers on textured surfaces (both mono- and multi-crystalline) without significant impact on the texture geometry, which would otherwise be detrimental to silicon solar cell electrical performance. The preservation of surface texturing, due to the near-conformal etching behaviour, also allows much deeper etch-backs than conventional methodologies. Deep etch-backs are of particular benefit for in-line diffused emitters which require a post-diffusion etch-back to increase cell efficiency by removal of heavily doped surface dead layers. Other applications of deep etch-backs include removal of surface rich layers on boron emitters and formation of selective emitters by masked etch back. In addition to dead layer removal, the KOH/NaOCl solution in accordance with the present embodiment is also very effective at removal of surface contaminants 406 (and as seen in the micrograph 460).

As a non-acidic solution, the KOH:NaOCl solution in accordance with the present embodiment is also compatible with SiNₓ and SiOₓ layers. This enables in-line parasitic junction removal after SiNₓ deposition or batch-based parasitic junction removal using the SiNₓ/SiOₓ stack as a mask layer. In addition, utilizing the KOH:NaOCl solution in accordance with the present embodiment provides a new method for edge isolation.

In addition, HF acid based etch-back solutions are extremely hazardous due the high concentrations required. The HF-free property of the KOH:NaOCl solution and the etch-back process in accordance with the present embodiment consequently significantly lowers the risk of etch-back processes and creates an alternate, environment-friendly option for etch-back processes.

In the KOH—NaOCl process, NaOCl is a strong oxidising agent. The chemical reactions are summarized in chemical formulas (1) to (3):

NaOCl [symbol] Na⁺+OCl⁻ (1)

2OCl⁻+H₂O [symbol] HOCl+OCl⁻+OH⁻ (2)

Si+2OCl⁻ [symbol] SiO₂+2Cl⁻ (3)

NaOCl ionizes in water to give hypochlorous acid (HOCl) and hypochlorite ions (OCL). The silicon etching rate is very small due to the availability of hydroxyl (OH⁻). Further, silicon reacts with the hypochlorous ions to form silicon dioxide (SiO₂). This reaction of KOH with silicon is given in chemical formula (4):

KOH [symbol] K⁺+OH⁻;Si+4OH⁻ [symbol] Si(OH)₄ (4)

wherein the silicon reacts with hydroxyl ions to form silicon hydroxide complex, Si(OH)₄.

The KOH etch rate is high for some crystal orientations (i.e., <100>), and very slow for others, i.e., along <111> orientation, leading to pyramid shaped surface texturing. The SiO₂ layer produced due to the presence of NaOCl acts as a barrier to fast silicon etching by KOH thereby creating a near-conformal etching behaviour on doped silicon surfaces. However, at much higher KOH concentration in the texturing KOH:NaOCl solution SiO₂ barrier becomes ineffective with higher, non-uniform Si-etching rates occurring and the formation of textured surfaces.

In accordance with the present embodiment, a slow, controlled, uniform and near-conformal etch-back process 510 is created using a totally different combination of KOH and NaOCl. One skilled in the art will realise that different concentrations can be used to tune the etching rate while keeping the solution in the near-conformal range.

The etch-back temperature range in accordance with the present embodiment is 80° C. to 82° C. Below 80° C., the etch rate by KOH becomes very slow and unable to etch through the SiO₂ layer formed by NaOCl. Above 82° C. NaOCl decomposes into oxygen and sodium chloride and, thus, NaOCl becomes unable to protect the SiO₂ layer from severe etching by KOH leading to undesirable non-uniform surface etching. Therefore, to maintain the uniformity of the etch-back solution, critical conditions must be controlled throughout the KOH—NaOCl etch-back process including chemical composition, bath temperature and process duration. Through such control a very uniform, isotropic and nearly conformal etch-back process can be achieved with a controllable etch rate in the range 10-300 nm/min depending on the property of the etched Si-surface. Because of the controllability of the etch rate, the total removal of the doped region is set by the total etch time, for a given solution composition, to reach the desired sheet resistance or surface concentration required for the solar cell being fabricated.

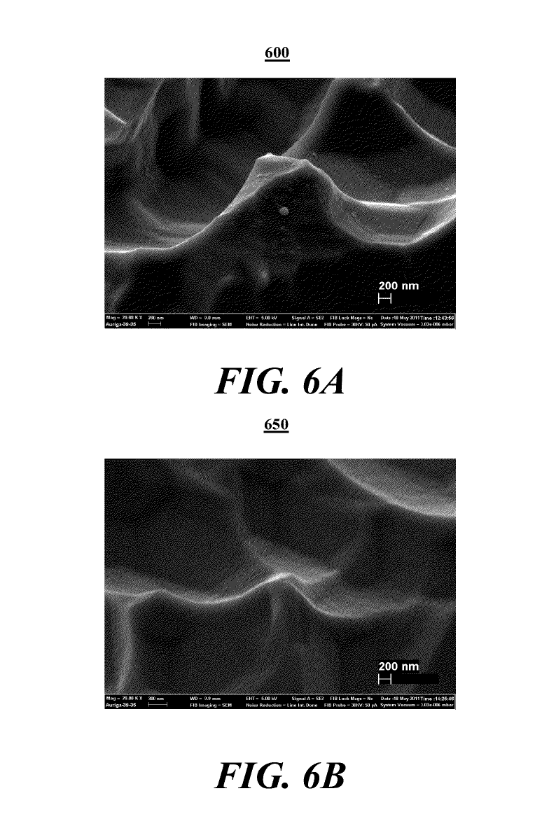

FIG. 6A illustrates a scanning electron microscope (SEM) micrograph 600 of an in-line phosphorus diffused, textured multi-crystalline silicon wafer after PSG removal and before etch-back using the KOH—NaOCl etch-back solution disclosed in accordance with the present embodiment. The texturing as seen in the micrograph 600 is essential for solar cells to lower reflection losses at the surface of the solar cell. Typical applications of HF-based etch-back solutions affects the surface texture and degrades the surface reflection, especially when deeper etch-backs are used. However, on applying the KOH—NaOCl etch-back in accordance with the present embodiment, the surface texture is largely unaffected by the etch-back as clearly seen in FIG. 6B which is a SEM micrograph 650 of the in-line phosphorus diffused layer after etch-back of the multicrystalline silicon wafer in accordance with the present embodiment. In addition to the texture-preserving etch-back, surface debris visible in the micrograph 600 is removed by the KOH—NaOCl etching solution as evidenced by the micrograph 650.

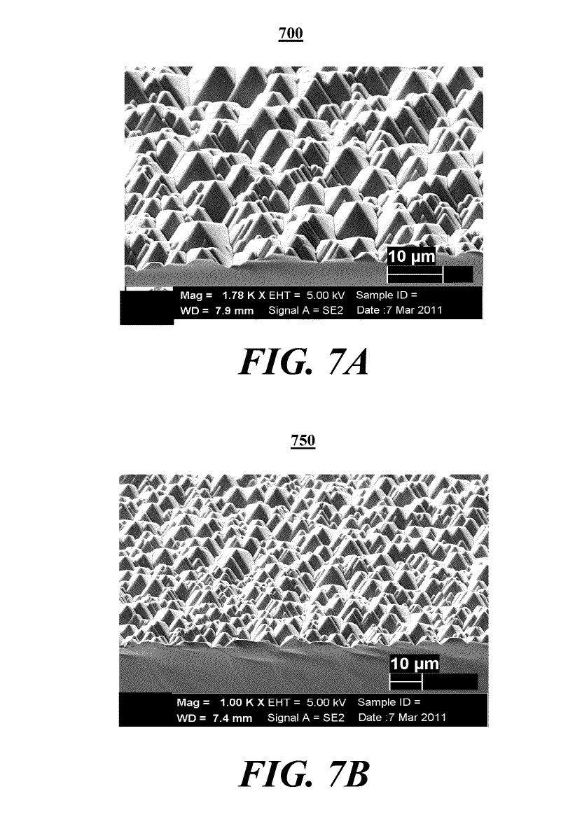

Referring to FIG. 7, the same phenomenon is observed on etch-back of tube-diffused boron emitters on silicon wafer solar cells. FIG. 7A illustrates a SEM micrograph 700 of a tube boron diffused layer after BSG removal and before etch-back of the crystalline silicon wafer and FIG. 7B illustrates a SEM micrograph 750 of the tube boron diffused layer after etch-back of the crystalline silicon wafer in accordance with the present embodiment.

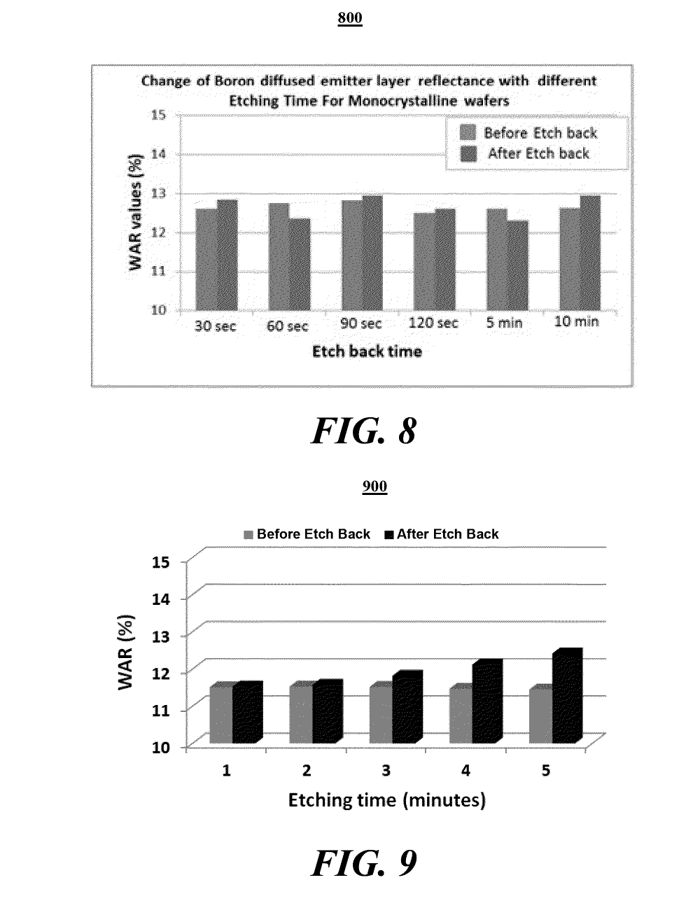

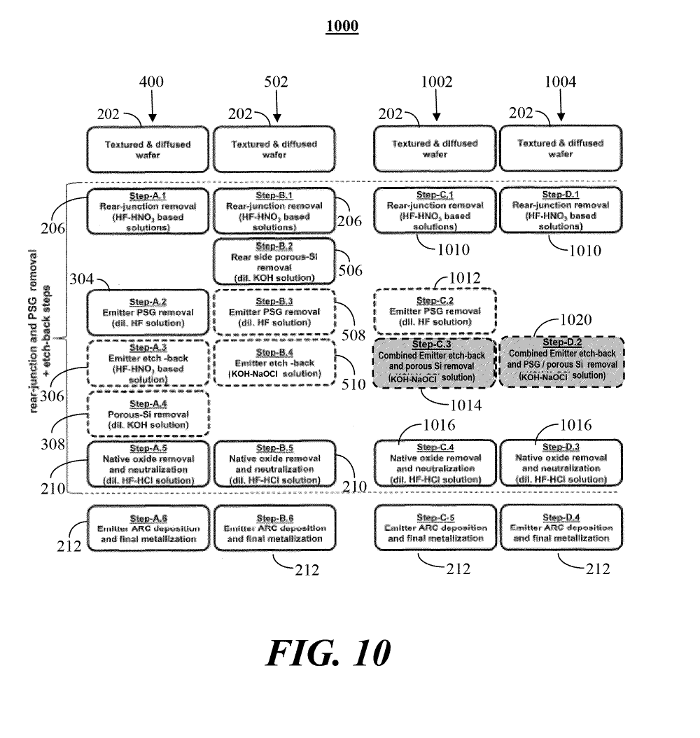

Referring to FIG. 8, a bar graph 800 depicts variations of weighted averages of reflectance (WAR) of a boron diffused layer before and after etch-back of different durations in accordance with the present embodiment. The results show a negligible variation in WAR for different etch-back durations up to at least six hundred seconds. The reflectance is weighted against 1 SUN solar intensity over AM1.5 spectrum. The near constancy of the WAR values of the textured wafers demonstrates the conformity of the textured surfaces after different durations of etch-back in accordance with the present embodiment. The KOH—NaOCl etch-back solution similarly presents negligible effect on texturing or short circuit current density on inline phosphorus diffused, textured mono-crystalline wafers as seen in a bar graph 900 in FIG. 9.

The preservation of surface texturing, due to the near-conformal etching behaviour in accordance with the present embodiment, allows much deeper etch-backs than can otherwise be applied. This allows more effective removal of surface dead layers thereby increasing solar cell efficiency, without the previous restriction of damage to surface texturing. Because the KOH—NaOCl solution is not HF-based, it does not etch dielectrics such as SiNₓ and SiOₓ. Thus, after SiNₓ deposition, either using horizontal in-line etch tooling (FIG. 1B), or batch-based tooling (FIG. 1A), parasitic junction removal in accordance with the present embodiment can be achieved using the SiNₓ/SiOₓ layer as a sacrificial or non-sacrificial mask to block the etch-back on one side of the wafer. The net result is single side removal of the parasitic junction. Even after eighteen minutes of silicon etching in the KOH—NaOCl etch-back in accordance with the present embodiment the SiNₓ is found to be intact.

In accordance with a first variant of the present embodiment, a new method for silicon wafer solar cell fabrication integrates parasitic junction removal and emitter etch-back into a shorter overall process. Conventional parasitic junction isolation and emitter etch-back approaches use up to five different process steps, with separated sequences for parasitic junction and emitter etch-back processes. This first variant of the present embodiment reduces the process to four steps or less while achieving both parasitic junction isolation and emitter etch back. One of the important features of the solution of the present embodiment is that the alkalinity of the KOH—NaOCl solution also dissolves the porous-silicon layer generated on the surface of the silicon wafer during a standard HF—HNO₃-based parasitic junction removal process, thereby enabling the porous silicon removal and etch-back steps to be combined into a single process step. Using the KOH—NaOCl solution for etch-back in accordance with the present embodiment also has the capability of etching through the phosphosilicate glass (PSG) layer thereby enabling further streamlining of the process sequence to three steps. The present embodiment has several positive impacts on both mono- and multi-crystalline silicon wafer solar cell technologies, including reducing the number of process steps and potentially enhancing device performance.

As seen in the process flow 300 (FIG. 3), the conventional wet-chemical parasitic junction removal 206 uses single-side wet chemical etching to remove the parasitic junction. The parasitic junction removal process requires three sub-steps: single-side etching 206 using a HF—HNO3 based solution, which removes the parasitic junction and also creates a porous silicon layer; immersion etching 308 in dilute alkali solution (KOH or sodium hydroxide, NaOH) to remove the porous silicon; and an immersion etching in a dilute HF—HCl solution to remove 304 the emitter PSG layer (i.e. front side), native oxides 210, and neutralise 210 any residual alkaline solution from the porous silicon removal step.

In accordance with this first variant of the present embodiment, an improved, low cost process is disclosed to enable integration of parasitic junction removal and the emitter etch-back process steps to achieve an overall shorter process sequence, with particular advantage for inline-diffused silicon wafer solar cells technology. However, one skilled in the art will recognise that the invention can also be usefully applied to tube-diffused emitters.

Parasitic junction removal is necessary to remove parasitic shunt resistance, between the front and rear surfaces of the wafer that is formed during the thermal diffusion of the emitter. The current state of the art uses a HF—HNO₃ based solutions for single-side etching to remove the parasitic junction, with subsequent alkaline etching, to remove porous silicon (Si) formed during the HF—HNO₃ etching, and dilute HF etching, to remove the front-side phosphosilicate glass (PSG) layer.

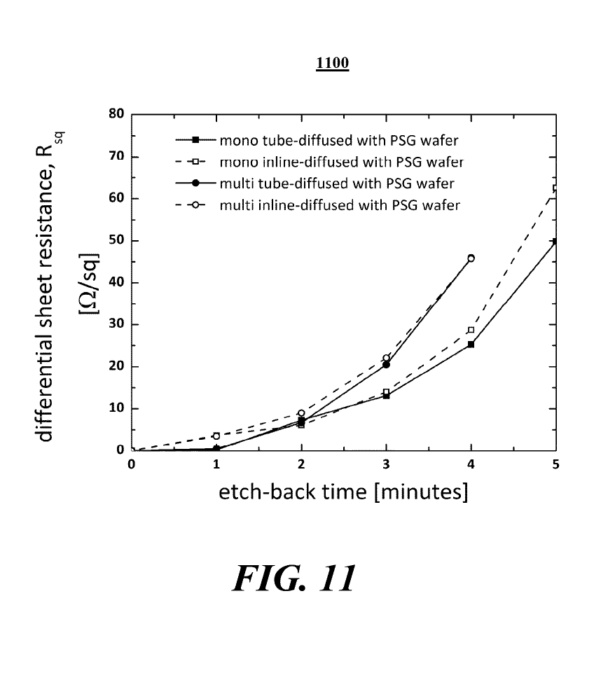

Referring to FIG. 10, a side-by-side comparison 1000 between the standard approaches for combined parasitic junction and PSG removal, and the etch-back process in accordance with the present embodiment, including this first variant of the present embodiment. The dashed boxes show the additional steps required for integrating the emitter etch-back process with the parasitic junction removal process. For simplicity, water rinse steps are not shown.

In accordance with this first variant to the present embodiment, the overall parasitic-junction-removal/emitter-etch-back processes can be stream-lined to four steps or less by exploiting the specific properties of the KOH—NaOCl etch-back solution as seen in process flows 1002, 1004. The use of KOH—NaOCl solution for etching negates the need for a separate porous silicon removal step by simultaneously performing the etch-back function and removing the porous silicon generated during the parasitic junction removal step (see the process flow 1002). In addition, the presence of large amount of chlorine in the KOH—NaOCl solution minimises the need for high HCl concentrations in the neutralization step. Optionally, the KOH—NaOCl solution can be applied in accordance with this first variant of the present embodiment to simultaneously remove the emitter-side PSG, thereby negating the need for a separate PSG removal step to further streamline the overall process (see the process flow 1004).

Conventional technologies to integrate the parasitic junction/PSG removal with emitter etch-back use two approaches: acidic etch-back solutions or non-acidic etch-back solutions. The process flow 400 is an example of such conventional technologies. In both acidic and non-acidic etch-back solutions the first step is the parasitic junction removal 206 in HF—HNO₃, which creates a porous silicon layer on the rear and leaves the PSG layer intact on the front-side emitter.

In the acidic approach, the PSG is removed from the emitter 304, and then the HF—HNO₃ based etch-back 306 is applied, which results in porous-Si generation. The porous silicon is subsequently dissolved on both sides of the wafer in dilute KOH (or NaOH) solution at step 308. Lastly, a dilute HF—HCl etch is applied 210 to neutralise any residual alkaline solution from the porous silicon removal step and remove any native oxides. A total of five process steps 206, 304, 306, 308, 210 are required

Similarly, a non-acidic approach (process 502) requires PSG removal 508 from the diffused emitter before emitter etch-back 510 using, for example, the KOH—NaOCl solution in accordance with the present embodiment. However, during etch-back, no porous-Si layer is grown, so no subsequent porous silicon removal step is required. Lastly, a dilute HF—HCl etch is applied 210 to neutralise any residual alkaline solution from the porous silicon removal step and remove any native oxides. A total of five process steps 206, 506, 508, 510, 210 are required

In accordance with this first variant of the present embodiment, the acidic etch-back step is removed and only the non-acidic KOH—NaOCl solution only etch-back step is performed (see the process flow 1002). After parasitic junction removal 1010 by HF—HNO₃ based solution, the emitter PSG layer is been removed 1012 in dilute HF. At this point, the front-side emitter is exposed but the porous silicon remains intact on the rear-side. The KOH—NaOCl solution is then applied 1014, which provides an emitter etch-back on the front side of the water while simultaneously removing the porous silicon on the rear-side. No separate porous silicon removal step is required. Lastly, a dilute HF—HCl etch is applied 1016 to neutralise any residual alkaline solution and remove any native oxides. As shown in FIG. 10, only four process steps are required for process 1002, compared to five process steps for the standard approach 400 and the approach 502.

A further reduction in process steps can be achieved by using the KOH—NaOCl solution to simultaneously dissolve the front-side PSG layer during the etch-back step (see process flow 1004 which combines steps 1012, 1014 of process flow 1002 into a single step 1020).

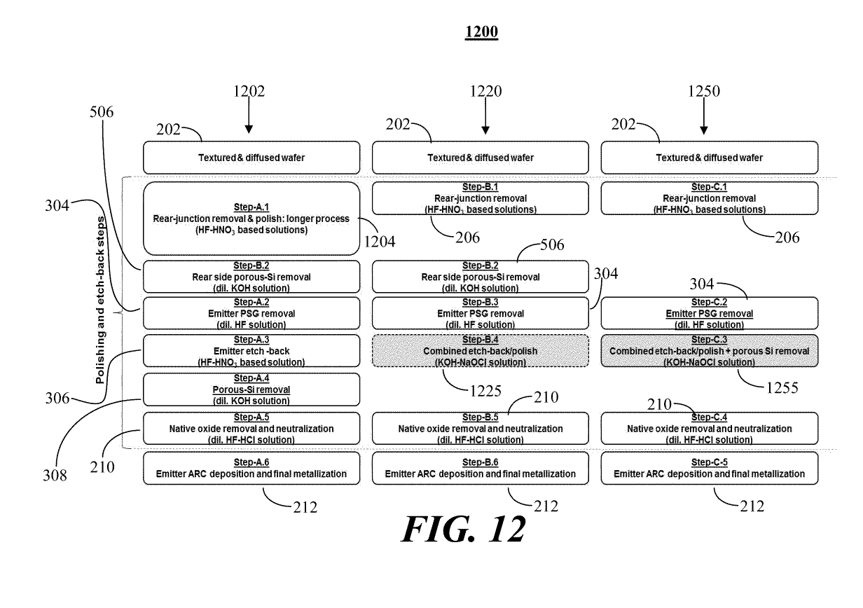

Referring to FIG. 11, a graph 1100 shows differential sheet resistance before and after etch-back using KOH—NaOCl solution in accordance with this first variant of the present embodiment for tube and inline-diffused mono- and multi-crystalline wafers with a PSG layer on the emitter. All wafers had a starting emitter having sheet resistance R_{sq}, approximately equal to 45 Ω/sq and are etched in the KOH—NaOCl solution for a one-minute to a five-minute duration. The graph 1100 shows that while during the first minute, the change in R_{sq} of the emitters is small (<4 Ω/sq), that this change in R_{sq} increases exponentially for further etching. This indicates that emitter etch-back can be predictably achieved without prior removal of the front-side PSG layer. Hence after the parasitic junction removal step 1010, the KOH—NaOCl solution 1020 can be applied directly. As shown in FIG. 10, this approach 1004 only requires three process steps, compared to five for the standard approach 400 and for the approach 502.

During the etch-back steps 1014, 1020, the alkalinity of this etch-back solution dissolves the rear-side porous-Si layer and performed emitter etch-back simultaneously. One skilled in the art will recognise that other solutions using a mixture of alkaline chemicals (including NaOH, KOH, etc.) and oxidiser chemicals (NaOCl, H₂O₂, KMnO₄, etc.) could also be used to achieve the combined porous-Si removal and etch-back process.

As shown in Table 1, the new method also reduces the number of overall process steps required.

TABLE 1

| | Parasitic junction and PSG removal + emitter etch-back | | | |
|---|---|---|---|---|
| | | | Proposed approaches | |
| | | | SERIS etch | |
| | Standard approaches | | based | SERIS etch |
| | HF—HNO₃ | SERIS etch | etch-back | based etch- |
| | based | based etch- | without | back with |
| Process steps | etch-back | back | PSG layer | PSG layer |
| Parasitic junction removal | ✓ | ✓ | ✓ | ✓ |
| in HF—HNO₃ based solution | | | | |
| Rear-side porous-Si | ✓ | x | x | x |
| removal | | | | |
| Emitter PSG removal | ✓ | ✓ | ✓ | x |
| Emitter etch-back | ✓ | ✓ | ✓ | ✓ |
| Porous-Si removal | ✓ | x | x | x |
| Native oxide removal and | ✓ | ✓ | ✓ | ✓ |
| neutralization | | | | |

In the current state-of-the-art, parasitic junction/PSG removal and emitter etch-back processes are largely separated processes. The present embodiment enables integration of the processes to achieve an overall shorter process sequence. In addition, present state-of-the-art approaches for parasitic junction/PSG removal and etch-back processes use five major process steps (using both acidic and non-acidic etch-back solutions). The present invention advantageously uses only a maximum of four steps, with the option to further reduce to three steps by elimination of the PSG removal step as seen in FIG. 10.

Emitter etch-back and rear-side polishing are important processes for improving solar cell efficiency. Typically these are separate processes due to inherently different process goals. In particular, an etch-back needs to be conformal to maintain surface texturing, whereas a polish etch is non-conformal to planarize the surface. In accordance with a second variant of the present embodiment, a method using a single etch solution, KOH—NaOCl, is described which is conformal (i.e. an etch-back) on doped surfaces, but non-conformal (i.e. a polish) on undoped surfaces. Single side etching is typically applied to silicon wafer solar cells to remove the parasitic junction, which leaves one side of the wafer doped whereas the opposite is undoped due to removal of the parasitic junction. By immersing the wafer in a heated KOH—NaOCl solution after removal of the parasitic junction, etch-back occurs on one side of the wafers (the doped side) while polishing occurs on the opposition side of the wafer (the undoped side). Thus, etch-back and polishing is achieved in a single process solution.

This second variant of the present embodiment discloses the use of a chemical etching process with a special recipe of hot KOH—NaOCl solution as a combined etch-back/polishing solution, which is also low concentration and non-acidic (hydrofluoric acid (HF)-free). On doped surfaces, the KOH—NaOCl acts as an etch-back, which provides a controlled, uniform and near-conformal etching behaviour that enables removal of unwanted heavily or depleted doped layers on textured surfaces (both mono- and multi-crystalline) without significant impact on the texture geometry that would otherwise be detrimental the silicon solar cell efficiency. Conversely, on undoped surfaces the KOH—NaOCl solution acts as a non-conformal polishing solution, which smooths the undoped surface. Consequently, etch-back and polishing can be simultaneously achieved by applying the KOH—NaOCl etching solution to a wafer where one surface is doped while the other side is undoped. Such doping asymmetry is commonly produced by the single side etching of silicon wafer solar cells used to remove the rear parasitic junction, thereby providing scope for integrating the combined etch-back/polishing process after the parasitic junction removal process.

Typically etch-back and polishing require separate process steps due to the inherently different process goals, namely conformal vs. non-conformal etching. Therefore this second variant of the present embodiment offers potential cost reduction for solar cell fabrication sequences that require etch-back and polishing steps. In addition, this second variant of the present embodiment can be applied in conjunction with other polishing methods to provide an additional stage of polishing during the etch-back process. Lastly, HF acid-based etch-back solutions are extremely hazardous due to the high concentrations required; therefore, the HF-free nature and the low concentration required of the KOH—NaOCl significantly lowers the risks and hazards of etch-back processes.

Referring to FIG. 12, a comparison 1200 of a process 1202 for etch-back and polishing is compared to a process 1220 in accordance with the second variant of the present embodiment which uses a combined etch-back/polish approach. A third process 1250 shows the additional process streamlining that could be achieved by applying the first variant of the present embodiment described in FIG. 10, whereby KOH—NaOCl can also be applied to remove the porous silicon produced during the preceding HF—HNO₃ etching.

Rear-side polishing (or planarization) is commonly applied during silicon wafer solar cell fabrication to achieve single side texturing of the silicon wafers, by etching off the textured surface on the rear side of the wafer. Typically this is achieved in HF—HNO₃ based solutions using a single side polishing-etch process, which is often combined with the removal of the rear parasitic junction 1204. Also, those skilled in the art will realize that polishing is typically a longer process than junction removal alone as a much deeper etching is required in order to planarize the rear surface. Planarization of solar cell surfaces is important for rear-passivated solar cells, such as aluminium local back surface field (Al-LBSF) solar cells, which require a polished rear surface to increase solar cell efficiency

When comparing the process 1202 with the process 1220 (a process in accordance with the second variant of the present embodiment), it can be seen that the process 1220 is shorter. Step 1225 combines etch-back and polish into a single step. The process 1250 shows the additional process streamlining that could be achieved by using the KOH—NaOCl solution to remove the porous silicon produced during the preceding HF—HNO₃ etching in a single step 1255 with the etch-back and the polish.

Thus, it can be seen that a solar cell fabrication process that overcomes the drawbacks of conventional etching process steps, such as providing an etch-back solution that is compatible with dielectrics, has been provided. Further, a solar cell fabrication process has been provided that does not have the safety risks and hazards present in HF-based etching process steps. In addition, we have disclosed fabrication process flows which can reduce cost by reducing the steps required. While exemplary embodiments have been presented in the foregoing detailed description of the invention, it should be appreciated that a vast number of variations exist.

It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of process steps described in the exemplary embodiment without departing from the scope of the invention as set forth in the appended claims.

1. A method for silicon wafer solar cell fabrication comprising:
etching a doped surface of the silicon wafer solar cell using a solution including sodium hypochlorite (NaOCl) and a hydroxide selected from the group comprising sodium hydroxide (NaOH) and potassium hydroxide (KOH).

2. The method in accordance with claim 1 further comprising removing surface contaminants including residual phosphosilicate glass (PSG), wherein the etching step comprises etching the surface of the silicon wafer after removing the PSG.

3. The method in accordance with claim 1 further comprising removing porous silicon before the etching step.

4. The method in accordance with claim 1 wherein the etching step comprises etching-back an emitter layer of the silicon wafer solar cell.

5. The method in accordance with claim 1 wherein the etching step comprises simultaneously removing porous silicon and etching-back an emitter layer of the silicon wafer solar cell.

6. The method in accordance with claim 5 wherein the etching step further includes simultaneously removing PSG.

7. The method in accordance with claim 1 wherein the etching step comprises simultaneously etching-back an emitter layer of the silicon wafer solar cell and polishing a surface of the emitter layer of the silicon wafer.

8. The method in accordance with claim 7 wherein the etching step further comprises simultaneously removing porous silicon from the surface of the silicon wafer.

9. The method in accordance with claim 8 wherein the etching step further includes simultaneously removing PSG from the surface of the silicon wafer.

10. The method in accordance with claim 1 further comprising after the etching step:
removing native oxide and neutralization thereof;
depositing an anti-reflective coating (ARC) on an outer surface of the emitter; and
performing final metallization.

11. The method in accordance with claim 10 wherein the step of native oxide removal and neutralization comprises removing native oxide and neutralization thereof using a diluted hydrofluoric-hydrochloric acid (HF—HCL) solution

12. The method in accordance with claim 1 further comprising before the etching step, the step of removing a parasitic junction.

13. The method in accordance with claim 12 wherein the step of removing the parasitic junction comprises removing the parasitic junction using a hydrofluoric-nitric acid (HF—HNO₃) based solution.

14. The method in accordance with claim 12 wherein the step of removing the parasitic junction comprises removing the parasitic junction using reactive ion etching.

15. A method for silicon wafer solar cell fabrication comprising:
using a solution including sodium hypochlorite (NaOCl) and either potassium hydroxide (KOH) or sodium hydroxide (NaOH) to simultaneously etch-back an emitter layer of the silicon wafer solar cell while removing porous silicon.

16. The method in accordance with claim 15 wherein the step further includes simultaneously using the solution to remove phosphosilicate glass (PSG).

17. The method in accordance with claim 15 further comprising:
removing native oxide and neutralization thereof;
depositing an anti-reflective coating (ARC) on an outer surface of the emitter; and
performing final metallization.

18. The method in accordance with claim 17 wherein the step of native oxide removal and neutralization comprises removing native oxide and neutralization thereof using a diluted hydrofluoric-hydrochloric acid (HF—HCl).

19. A method for silicon wafer solar cell fabrication comprising:
using a solution including sodium hypochlorite (NaOCl) and either potassium hydroxide (KOH) or sodium hydroxide (NaOH) to simultaneously etch-back an emitter layer of the silicon wafer solar cell while polishing a surface of the emitter layer of the silicon wafer.

20. The method in accordance with claim 19 wherein the step further includes simultaneously using the solution to remove phosphosilicate glass (PSG) from the surface of the silicon wafer.

21. The method in accordance with claim 19 wherein the step further comprises simultaneously using the solution to remove porous silicon from the surface of the silicon wafer.
